(19) United States
(12) Patent Application Publication
(10) Pub. No.: US 2013/0104973 A1
(43) Pub. Date: May 2, 2013

(54) CONDUCTIVE PASTE, AND ELECTRONIC DEVICE AND SOLAR CELL INCLUDING ELECTRODE FORMED USING THE CONDUCTIVE PASTE

(71) Applicants: Sang Soo JEE, Hwaseong-si (KR); Suk Jun KIM, Suwon-si (KR); Haeng Deog KOH, Hwaseong-si (KR); Yun Hyuk CHOI, Seoul (KR); Eun Sung LEE, Seoul (KR)

(72) Inventors: Sang Soo JEE, Hwaseong-si (KR); Suk Jun KIM, Suwon-si (KR); Haeng Deog KOH, Hwaseong-si (KR); Yun Hyuk CHOI, Seoul (KR); Eun Sung LEE, Seoul (KR)

(73) Assignee: SAMSUNG ELECTRONICS CO., LTD., Suwon-si (KR)

(21) Appl. No.: 13/605,855

(22) Filed: Sep. 6, 2012

(30) Foreign Application Priority Data
Oct. 26, 2011 (KR) 10-2011-0109848

(51) Int. Cl. H01B 1/02; H01B 1/12; H01B 1/08; H01L 31/0224

(52) U.S. Cl. 136/256; 252/500; 252/519.3; 252/512; 252/514; 252/515; 252/513

(57) ABSTRACT

A conductive paste includes a conductive powder, a metallic glass, an inorganic additive for fire-through, and an organic vehicle, and an electronic device and a solar cell including an electrode formed using the conductive paste.

### CROSS-REFERENCE TO RELATED APPLICATION

This application claims priority to and the benefit of Korean Patent Application No. 10-2011-0109848 filed in the Korean Intellectual Property Office on Oct. 26, 2011, the entire contents of which are incorporated herein by reference.

### BACKGROUND

1. Field

Example embodiments relate to a conductive paste, and an electronic device and a solar cell including an electrode formed using the conductive paste.

2. Description of the Related Art

A solar cell is a photoelectric conversion device that transforms solar energy into electrical energy, and has attracted much attention as a potentially infinite and pollution-free next generation energy source.

A solar cell includes p-type and n-type semiconductors. When a photoactive layer in the semiconductors absorbs light and generates an electron-hole pair (“EHP”), the electrons and the holes respectively move into the n-type and p-type semiconductors and are collected in electrodes of the solar cell, thus producing electrical energy.

On the other hand, a solar cell may include an anti-reflection coating (ARC) layer. The anti-reflection coating layer may decrease reflectance of light on the surface of a solar cell and increase selectivity of light in a particular wavelength region, improving efficiency of the solar cell.

However, the anti-reflection coating layer is made of a non-conductive material and may hinder charges from moving from a semiconductor layer to an electrode. Accordingly, the anti-reflection coating layer between the semiconductor layer and the electrode may be selectively removed.

The removal of the anti-reflection coating layer may be performed using photolithography or a laser ablation. However, this additional process may cause additional time and cost. Alternately, the anti-reflection coating layer may be removed through a chemical reaction of glass frit. The glass frit may be included in a conductive paste for an electrode. However, the glass frit is a non-conductive material, and thus, deteriorates conductivity of an electrode.

### SUMMARY

Example embodiments provide a conductive paste securing conductivity of an electrode without an additional process. Example embodiments also provide an electronic device including an electrode formed by using the conductive paste. Example embodiments also provide a solar cell including an electrode formed by using the conductive paste.

According to example embodiments, a conductive paste may include a conductive powder, a metallic glass, an inorganic additive for fire-through, and an organic vehicle.

The inorganic additive for fire-through may be fired through a film including one of nitride, oxide, and a combination thereof at a temperature ranging from about 200° C. to about 1,000° C. The film may include one of silicon nitride, silicon oxide, titanium nitride, titanium oxide, aluminum nitride, aluminum oxide, and a combination thereof.

The inorganic additive for fire-through may include at least one of a metal having a larger oxidation capability than the one of the nitride, oxide, and combination thereof, and an oxide thereof.

The inorganic additive for fire-through may include at least one of tin (Sn), zinc (Zn), strontium (Sr), magnesium (Mg), silver (Ag), lead (Pb), bismuth (Bi), molybdenum (Mo), technetium (Tc), ruthenium (Ru), rhodium (Rh), tungsten (W), rhenium (Re), osmium (Os), iridium (Ir), platinum (Pt), vanadium (V), manganese (Mn), chromium (Cr), iron (Fe), copper (Cu), cobalt (Co), palladium (Pd), nickel (Ni), and oxides thereof.

The inorganic additive for fire-through may include at least one of tin (Sn), zinc (Zn), strontium (Sr), magnesium (Mg), tin oxide (SnO₂), silver oxide (Ag₂O), lead oxide (PbO), zinc oxide (ZnO), vanadium oxide (V₂O₃), manganese oxide (MnO), chromium oxide (Cr₂O₃), iron oxide (Fe₂O₃), copper oxide (CuO), cobalt oxide (CoO), palladium oxide (PdO), and nickel oxide (NiO).

The inorganic additive for fire-through may decrease contact resistance of the conductive paste. The inorganic additive for fire-through may be included in an amount of about 0.1 wt % to about 35 wt % based on a total weight of the conductive paste.

The conductive powder, the metallic glass, and the organic vehicle may be respectively included in an amount of about 30 wt % to about 99 wt %, about 0.1 wt % to about 20 wt %, and a balance thereof based on a total weight of the conductive paste. The conductive powder may include one of silver (Ag), aluminum (Al), copper (Cu), nickel (Ni), and a combination thereof.

According to example embodiments, an electronic device may include an electrode formed by using the aforementioned conductive paste.

The electrode may have a contact resistance of less than or equal to about 100 mΩcm2. The electrode may have resistivity of less than or equal to about 100 μΩcm.

According to example embodiments, a solar cell may include a semiconductor substrate and an electrode formed by using the aforementioned conductive paste, the electrode being electrically connected to the semiconductor substrate.

The solar cell may further include an anti-reflection coating layer on one side of the semiconductor substrate, and the electrode may be fired through the anti-reflection coating layer and contacts the semiconductor substrate.

The electrode may have a contact resistance of less than or equal to about 100 mΩcm2. The electrode may have resistivity of less than or equal to about 100 μΩcm.

### BRIEF DESCRIPTION OF THE DRAWINGS

These and/or other aspects will become apparent and more readily appreciated from the following description of example embodiments, taken in conjunction with the accompanying drawings of which:

FIG. 1 is a cross-sectional view showing a solar cell according to example embodiments,

FIGS. 2 to 6 are cross-sectional views showing a method of manufacturing a solar cell of FIG. 1,

FIG. 7 is a schematic diagram showing electrical characteristic evaluations of the electrode samples according to an example and a comparative example.

### DETAILED DESCRIPTION

Example embodiments will hereinafter be described in detail and may be easily performed by those who have common knowledge in the related art. This disclosure may, however, be embodied in many different forms and should not be construed as limited to example embodiments set forth herein.

It will be understood that when an element is referred to as being ed to lated om the following description of example embodiments, taken in conjunction with the accompanying drawings ofg elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms n element is referred to as being the following description of example embodiments, takelement, there are no intervening elements present. As used herein the term t is referred to as being the following description of example embodiments, takelement, there are no the accompanying drawings ofg elements may be present. In contrast, when anon, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

As used herein, the term “element” may refer to a metal and/or a semi-metal.

A conductive paste according to example embodiments may include conductive powder, metallic glass, an inorganic additive for a fire-through, and an organic vehicle.

The conductive powder may include a silver (Ag)-containing metal (e.g., silver or a silver alloy), an aluminum (AD-containing metal (e.g., aluminum or an aluminum alloy), a copper (Cu)-containing metal (e.g., copper (Cu) or a copper alloy), a nickel (Ni)-containing metal (e.g., nickel (Ni) or a nickel alloy), or a combination thereof. However, the conductive powder is not limited thereto, and may include other metals and additives other than the metals.

The conductive powder may have a size (e.g., an average largest particle size) ranging from about 1 nm to about 50 μm. The conductive powder may be included in an amount ranging from about 30 wt % to about 99 wt % based on the total weight of the conductive paste.

The metallic glass is an alloy with a disordered atomic structure including two or more metals and/or semi-metals. The metallic glass may be an amorphous metal. Herein, the metallic glass may have an amorphous portion formed by rapidly solidifying the melted metals and/or semi-metals. The metallic glass may remain in the amorphous portion, which is formed in a melted state at higher temperatures, when at room temperature. Thus, the metallic glass may be distinguished from a normal metal, which has a regular crystalline structure at room temperature, and liquid metal, which has a liquid form at room temperature.

The amorphous portion may take about 50 to about 100 volume % of the metallic glass, for example, about 70 to 100 volume %, or about 90 to 100 volume %. The metallic glass has a lower specific resistivity and thus conductivity, unlike a glass (e.g., a silicate).

The metallic glass may be an alloy of a transition element, a noble metal, a rare earth element metal, an alkali metal, an alkaline-earth metal, and/or a semi-metal.

The metallic glass may include, for example, an alloy including at least two of an element with lower resistivity, an element forming a solid solution with the conductive powder, and an element with higher oxidation properties.

The element with lower resistivity may be a lower resistant metal determining conductivity of a metallic glass, for example, having lower resistivity of about 100 μΩcm or lower, for example, about 15 μΩcm or lower.

A lower resistant metal may include, for example, at least one of silver (Ag), copper (Cu), gold (Au), aluminum (Al), calcium (Ca), beryllium (Be), magnesium (Mg), sodium (Na), molybdenum (Mo), tungsten (W), tin (Sn), zinc (Zn), nickel (Ni), potassium (K), lithium (Li), iron (Fe), palladium (Pd), platinum (Pt), rubidium (Rb), chromium (Cr), and strontium (Sr).

The element forming a solid solution with a conductive powder may be a component capable of forming a solid solution with the conductive powder at greater than or equal to the glass transition temperature (Tg) of the metallic glass.

For example, when an electrode for a solar cell is formed by using the conductive paste including metallic glass on a semiconductor substrate, the metallic glass is softened due to the heat treatment, and the conductive powder forms a solid solution with an element forming a solid solution and may be diffused inside the softened metallic glass. Finally, the conductive powder may be diffused into a semiconductor substrate, and thus many crystalline particles of the conductive powder are formed on the surface of the semiconductor substrate. The crystalline particles of the conductive powder produced on the surface of the semiconductor substrate may effectively transfer charges produced by solar light to an electrode, improving efficiency of a solar cell.

The element forming a solid solution with a conductive powder may be selected from elements with a heat of mixing value of less than 0.

For example, when the conductive powder includes silver (Ag), the element forming a solid solution with the conductive powder may be at least one of lanthanum (La), cerium (Ce), praseodymium (Pr), promethium (Pm), samarium (Sm), lutetium (Lu), yttrium (Y), neodymium (Nd), gadolinium (Gd), terbium (Tb), dysprosium (Dy), holmium (Ho), erbium (Er), thulium (Tm), thorium (Th), calcium (Ca), scandium (Sc), barium (Ba), ytterbium (Yb), strontium (Sr), europium (Eu), zirconium (Zr), lithium (Li), hafnium (Hf), magnesium (Mg), phosphorus (P), arsenic (As), palladium (Pd), gold (Au), plutonium (Pu), gallium (Ga), germanium (Ge), aluminum (Al), zinc (Zn), antimony (Sb), silicon (Si), tin (Sn), titanium (Ti), cadmium (Cd), indium (In), platinum (Pt), and mercury (Hg).

For example, when the conductive powder includes aluminum (Al), the element forming a solid solution with the conductive powder may include at least one of palladium (Pd), zirconium (Zr), platinum (Pt), thorium (Th), promethium (Pm), gadolinium (Gd), terbium (Tb), lutetium (Lu), hafnium (Hf), scandium (Sc), yttrium (Y), lanthanum (La), cerium (Ce), praseodymium (Pr), neodymium (Nd), samarium (Sm), dysprosium (Dy), holmium (Ho), erbium (Er), thulium (Tm), plutonium (Pu), rhodium (Rh), titanium (Ti), iridium (Ir), uranium (U), nickel (Ni), gold (Au), ruthenium (Ru), calcium (Ca), technetium (Tc), barium (Ba), ytterbium (Yb), manganese (Mn), cobalt (Co), europium (Eu), tantalum (Ta), strontium (Sr), niobium (Nb), osmium (Os), vanadium (V), phosphorus (P), iron (Fe), chromium (Cr), rhenium (Re), arsenic (As), molybdenum (Mo), lithium (Li), silver (Ag), magnesium (Mg), silicon (Si), germanium (Ge), tungsten (W), and copper (Cu).

For example, when the conductive powder includes copper (Cu), the element forming a solid solution with the conductive powder may be at least one of thorium (Th), lutetium (Lu), scandium (Sc), zirconium (Zr), promethium (Pm), terbium (Tb), erbium (Er), thulium (Tm), gadolinium (Gd), yttrium (Y), praseodymium (Pr), neodymium Nd, samarium (Sm), dysprosium (Dy), holmium (Ho), lanthanum (La), cerium (Ce), hafnium (Hf), palladium (Pd), calcium (Ca), platinum (Pt), ytterbium (Yb), europium (Eu), plutonium (Pu), titanium (Ti), gold (Au), barium (Ba), strontium (Sr), phosphorus (P), uranium (U), lithium (Li), arsenic (As), magnesium (Mg), rhodium (Rh), silicon (Si), and aluminum (Al).

The element with higher oxidation properties is a component with higher oxidation properties than the element with lower resistivity and the element forming a solid solution with a conductive powder, and may be oxidized prior to the other elements in order to prevent or inhibit their oxidation.

The conductive paste including metallic glass is in general processed under the ambient atmosphere and may be more easily exposed to oxygen in the air. Herein, when the element with lower resistivity is oxidized, the conductive paste may have deteriorated conductivity. When the element forming a solid solution with a conductive powder is oxidized, the conductive powder may have lower solid properties.

Accordingly, an element with higher oxidation properties than the element with lower resistivity and the element forming a solid solution with a conductive powder is included in the conductive paste and is primarily oxidized, and thus forms a stable oxide layer on the surface of a metallic glass and may prevent or inhibit oxidation of the other components of the metallic glass. Resultantly, the element with higher oxidation properties may prevent or inhibit performance deterioration of a conductive paste due to oxidation of other elements of a metallic glass.

The element with higher oxidation properties may have a larger absolute value of Gibbs free energy of oxide formation (ΔfG0) than the element with lower resistivity and the element forming a solid solution with a conductive powder. The larger absolute value of Gibbs free energy of oxide formation refers to an easier oxidation property. For example, the element with higher oxidation properties may have a higher absolute value of Gibbs free energy of oxide formation than 100 kJ/mol.

The metallic glass may be an alloy of at least two selected from the element with lower resistivity, the element forming a solid solution with a conductive powder, and the element with higher oxidation properties. Accordingly, the element with lower resistivity, the element forming a solid solution with a conductive powder, and the element with higher oxidation properties may be variously combined, thus forming a metallic glass.

For example, when the element with lower resistivity is marked as “A”, “A1”, and/or “A2”, the element forming a solid solution with a conductive powder is marked as “B”, “B1”, and/or “B2”, and the element with higher oxidation properties may be marked as “C”, “C1”, and/or “C2”. The metallic glass may be various alloys including two or more components (e.g., A-B, A-C, B-C, A-B-C, A-A1-B-B1, A-A1-B-B1-C, and A-A1-B-B1-C-C1), for example, alloys including 2 or more components to 6 components, but is not limited thereto.

Herein, the element with lower resistivity in terms of conductivity may be necessarily included and may form an alloy with at least one of the element forming a solid solution with a conductive powder and the element with higher oxidation properties.

The metallic glass may be included in an amount of about 0.1 to 20 wt % based on the total weight of the conductive paste.

The inorganic additive for fire-through is a component that is fired through a predetermined or given film at a firing temperature. Herein, the firing temperature refers to a temperature for firing an electrode when the electrode is formed using a conductive paste, and the fire-through refers to a component that chemically reacts with another component forming the film during the firing and penetrates the film.

The firing temperature may be, for example, in a range of about 200 to about 1000° C. The film may include a nitride, oxide, or a combination thereof, for example, silicon nitride, silicon oxide, titanium nitride, titanium oxide, aluminum nitride, aluminum oxide, or a combination thereof. The film may be at least one of an anti-reflection coating layer and a passivation film.

The inorganic additive for fire-through may include at least one of a metal with larger oxidation capability than the nitride, the oxide, or a combination thereof, and an oxide thereof. Accordingly, the nitride, the oxide, or a combination thereof may be oxidized and the inorganic additive may be reduced by firing, and thus penetrates the film.

The inorganic additive for fire-through may include at least one of tin (Sn), zinc (Zn), strontium (Sr), magnesium (Mg), silver (Ag), lead (Pb), bismuth (Bi), molybdenum (Mo), technetium (Tc), ruthenium (Ru), rhodium (Rh), tungsten (W), rhenium (Re), osmium (Os), iridium (Ir), platinum (Pt), vanadium (V), manganese (Mn), chromium (Cr), iron (Fe), copper (Cu), cobalt (Co), palladium (Pd), nickel (Ni), and oxides thereof.

The inorganic additive for fire-through may include, for example, at least one of tin (Sn), zinc (Zn), strontium (Sr), magnesium (Mg), tin oxide (SnO₂), silver oxide (Ag₂O), lead oxide (PbO), zinc oxide (ZnO), vanadium oxide (V₂O₃), manganese oxide (MnO), chromium oxide (Cr₂O₃), iron oxide (Fe₂O₃), copper oxide (CuO), cobalt oxide (CoO), palladium oxide (PdO) and nickel oxide (NiO). The inorganic additive for fire-through may also decrease contact resistance of the conductive paste.

In this way, when a conductive paste including the inorganic additive for fire-through is applied to a film (e.g., an anti-reflection coating layer and/or a passivation film), the conductive paste may selectively penetrate the film without additional photolithography or laser ablation, which may make a process simpler and decrease costs.

In addition, when the conductive paste is applied to form an electrode for a solar cell, an anti-reflection coating layer may be penetrated by the inorganic additive for fire-through in the conductive paste, thus the conductive paste including the metallic glass with no fire-through capability, unlike a conventional glass frit having fire-through capability, may be simultaneously used with the anti-reflection coating layer.

In addition, the inorganic additive for fire-through is included in a conductive paste and thus may decrease contact resistance of the conductive paste.

The inorganic additive for fire-through may be included in an amount of about 0.1 wt % to 35 wt % based on the total weight of the conductive paste. When the inorganic additive for fire-through is included within the range, the inorganic additive may be fired through a film and maintain lower contact resistance.

The organic vehicle may include an organic compound mixed with the conductive powder and the metallic glass imparting viscosity to the organic vehicle, and a solvent dissolving these components.

The organic compound may include, for example, at least one selected from a (meth)acrylate-based resin, a cellulose resin (e.g., ethyl cellulose), a phenol resin, an alcohol resin, tetrafluoroethylene (TEFLON), and a combination thereof and may further include an additive (e.g., a dispersing agent, a surfactant, a thickener, or a stabilizer).

The solvent may be any solvent dissolving the above compounds, and may include, for example, at least one selected from terpineol, butylcarbitol, butylcarbitol acetate, pentanediol, dipentyne, limonene, ethylene glycol alkylether, diethylene glycol alkylether, ethylene glycol alkylether acetate diethylene glycol alkylether acetate, diethylene glycol dialkylether acetate, triethylene glycol alkylether acetate, triethylene glycol alkylether, propylene glycol alkylether, propylene glycol phenylether, dipropylene glycol alkylether, tripropylene glycol alkylether, propylene glycol alkylether acetate, dipropylene glycol alkylether acetate, tripropylene glycol alkyl ether acetate, dimethylphthalic acid, diethylphthalic acid, dibutylphthalic acid, and desalted water.

The organic vehicle may be included at a balance amount excluding the solid components. The conductive paste may be applied by a screen printing method to form an electrode for an electronic device.

Herein, the electrode may have less than or equal to about 100 mΩcm2 of contact resistance. When the electrode has contact resistance within the range, the electrode may effectively decrease power loss, improving efficiency of an electronic device, specifically a solar cell. Specifically, the electrode may have contact resistance ranging from about 1 μΩcm2 to about 100 mΩcm2.

In addition, the electrode may have resistivity of less than or equal to about 100 μΩcm. When the electrode has resistivity within the range, the electrode may effectively decrease power loss, improving efficiency of an electronic device, specifically a solar cell. Specifically, the electrode may resistivity ranging from about 1 μΩcm to about 100 μΩcm within the above range. The electronic device may be a solar cell.

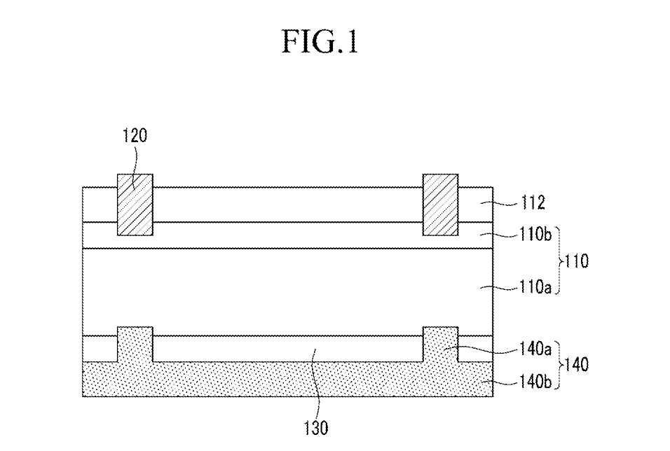

FIG. 1 is a cross-sectional view showing a solar cell according to example embodiments.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

In addition, “a front side” refers to a side receiving solar energy, and “a rear side” refers to a side opposite to the front side hereinafter.

Hereinafter, for the better understanding and ease of description, the upper and lower positional relationship will be described with respect to a semiconductor substrate 110, but is not limited thereto.

Referring to FIG. 1, a solar cell according to example embodiments may include a semiconductor substrate 110 including a lower semiconductor layer 110a and an upper semiconductor layer 110b.

The semiconductor substrate 110 may be formed of a crystalline silicon or a compound semiconductor. The crystalline silicon may be, for example, a silicon wafer. One of the lower semiconductor layer 110a and the upper semiconductor layer 110b may be a semiconductor layer doped with a p-type impurity, and the other may be a semiconductor layer doped with an n-type impurity. For example, the lower semiconductor layer 110a may be a semiconductor layer doped with a p-type impurity, and the upper semiconductor layer 110b may be a semiconductor layer doped with an n-type impurity. Herein, the p-type impurity may be a Group III element (e.g., boron (B)), and the n-type impurity may be a Group V element (e.g., phosphorus (P)).

The surface of the upper semiconductor layer 110b may be subjected to surface texturing. The surface-textured upper semiconductor layer 110b may have protrusions and depressions, for example, in a pyramid shape, or a porous structure, for example, in a honeycomb shape. The surface-textured upper semiconductor layer 110b may have an enlarged surface area to enhance the light-absorption rate and decrease reflectivity, resultantly improving efficiency of a solar cell.

On the upper semiconductor layer 110b, an anti-reflection coating (ARC) layer 112 is formed. The anti-reflection coating layer 112 may be formed of an insulating material absorbing less light, for example, a nitride, oxide, or a combination thereof. The nitride, oxide, or combination thereof may include, for example, silicon nitride, silicon oxide, titanium nitride, titanium oxide, aluminum nitride, aluminum oxide, or a combination thereof.

The anti-reflection coating layer 112 may be, for example, about 200 to about 1500 Å thick. The anti-reflection coating layer 112 is formed on the front side of the semiconductor substrate 110 receiving solar energy, and thus may decrease reflectance of light and increase selectivity of light in a particular wavelength region. In addition, the anti-reflection coating layer 112 may improve the contact characteristic with silicon at the surface of the semiconductor substrate 110, increasing efficiency of a solar cell.

On the anti-reflection coating 112, a plurality of front electrodes 120 are formed. The front electrodes 120 are disposed in parallel along one direction of the semiconductor substrate 110, and penetrate the anti-reflection coating layer 112 and contact the upper semiconductor layer 110b.

The front electrodes 120 may be formed by a screen printing method using the aforementioned conductive paste and designed as a grid pattern, considering shadowing loss and sheet resistance.

A conductive buffer layer (not shown) is disposed between the front electrodes 120 and the upper semiconductor layer 110b. The buffer layer is formed through melting of metallic glass included in the conductive paste. As aforementioned, because the metallic glass has conductivity, the buffer layer made from the metallic glass may provide a path through which charges may move between the upper semiconductor layer 110b and the front electrodes 120, and thus decrease the loss of charges when the charges move from the upper semiconductor layer 110b to the front electrodes 120.

A bus bar electrode (not shown) may be disposed on the front electrodes 120. The bus bar electrode connects adjacent solar cells during the assembly of a plurality of solar cells.

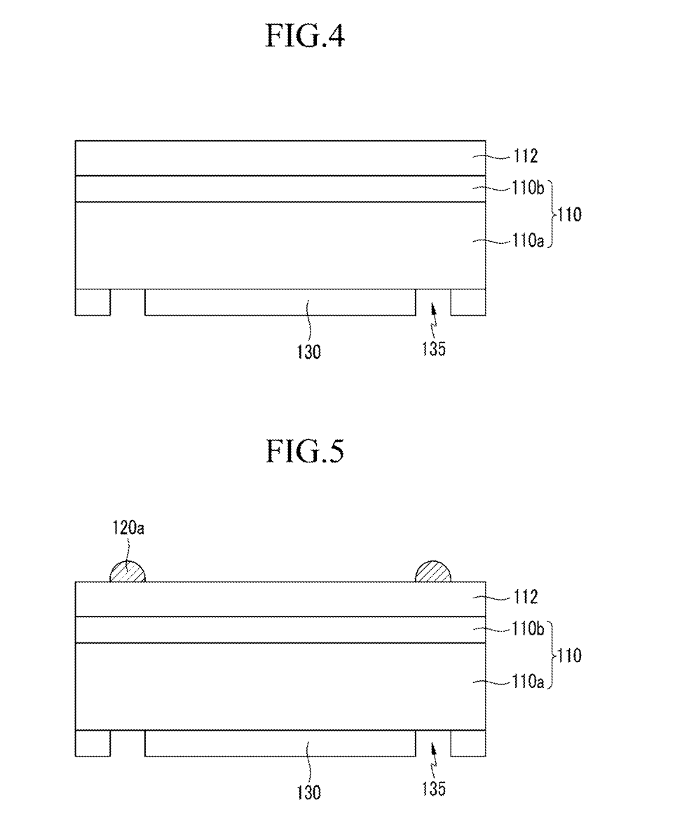

A dielectric layer 130 is disposed under the semiconductor substrate 110. The dielectric layer 130 may increase efficiency of a solar cell by preventing or inhibiting recombination of electric charges and leakage of a current. The dielectric layer 130 may have a plurality of contact holes 135 (see FIG. 4), and the semiconductor substrate 110 and a rear electrode 140 that will be described later may contact through the contact holes 135.

The dielectric layer 130 may be formed of silicon oxide, silicon nitride, aluminum oxide, or a combination thereof, and may have a thickness of about 100 Å to about 2000 Å. The dielectric layer 130 may be omitted as needed.

The rear electrode 140 is disposed under the dielectric layer 130. The rear electrode 140 may be formed of a conductive material, for example, an opaque metal (e.g., aluminum (Al)). The rear electrode 140 may be formed by a screen printing method using a conductive paste in the same manner as the front electrode 120.

The rear electrode 140 includes a plurality of contact portions 140a contacting the lower semiconductor layer 110a through the contact holes 135 in the dielectric layer 130, and a front portion 140b on the rear side of the semiconductor substrate 110.

A back surface field (BSF) may be produced where the lower semiconductor layer 110a of the semiconductor substrate 110 contacts the contact portion 140a of the rear electrode 140. The back surface field is an internal electric field formed by aluminum serving as a p-type impurity, for example, when the aluminum contacts the silicon, and thus may prevent or inhibit electrons from moving toward the rear side of the semiconductor substrate 110. Accordingly, the back surface field may prevent or inhibit charges from being recombined and disappearing at the rear side of the semiconductor substrate 110 and thus increase efficiency of a solar cell.

The front portion 140b of the rear electrode 140 reflects light passing through the semiconductor substrate 110 back to the semiconductor substrate 110, and thus may prevent or inhibit loss of the light, thereby increasing efficiency.

The rear electrode 140 may include a buffer layer (not shown) located in a region contacting the lower semiconductor layer 110a, and a rear electrode portion (not shown) located in a region other than the buffer layer and including a conductive material like the front electrode.

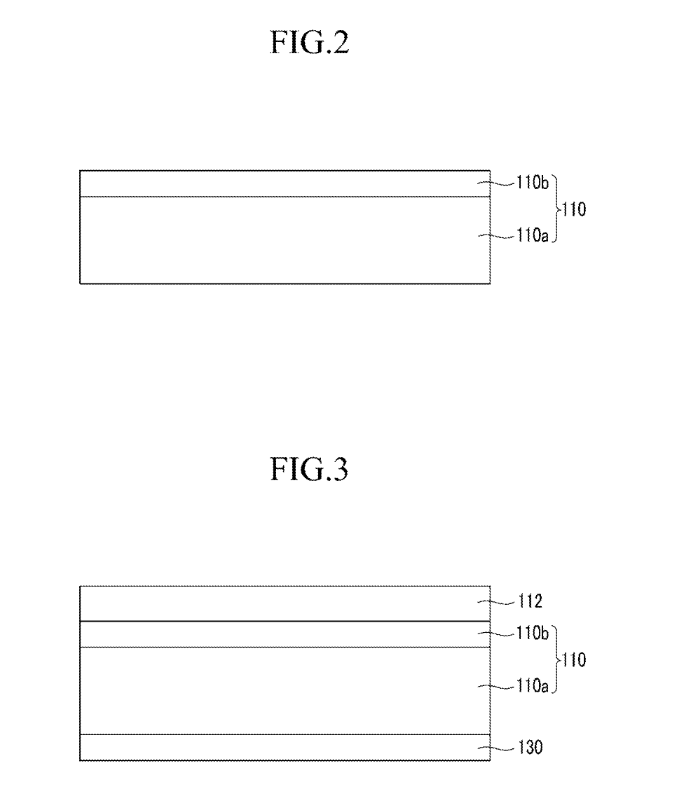

Hereinafter, a method of manufacturing the solar cell is illustrated referring to FIGS. 2 to 6 as well as FIG. 1. FIGS. 2 to 6 are cross-sectional views sequentially showing a solar cell of FIG. 1.

A semiconductor substrate 110 (e.g., a silicon wafer) is prepared. Herein, the semiconductor substrate 110 may be doped with, for example, a p-type impurity.

The surface of the semiconductor substrate 110 is textured. The surface texturing may be performed in a wet method using, for example, a strong acid (e.g., nitric acid and hydrofluoric acid) or strong base (e.g., sodium hydroxide), or in a dry method using plasma.

Referring to FIG. 2, an n-type impurity is doped in the semiconductor substrate 110. The n-type impurity may be doped by diffusing POCl₃, or H₃PO₄ at higher temperatures. Accordingly, the semiconductor substrate 110 includes a lower semiconductor layer 110a and the upper semiconductor layer 110b having impurities different from each other.

Referring to FIG. 3, an anti-reflection coating layer 112 and a dielectric layer 130 are respectively formed on the front and rear sides of the semiconductor substrate 110. The anti-reflection coating layer 112 and the dielectric layer 130 may be formed of, for example, silicon nitride and silicon oxide, in a plasma enhanced chemical vapor deposition (PECVD) method. However, the anti-reflection coating layer 112 and the dielectric layer 130 are not limited thereto but may be formed of other materials and methods. The dielectric layer 130 may be omitted.

Referring to FIG. 4, a part of the dielectric layer 130 is removed to form a plurality of contact holes 135 and to expose a portion of the lower semiconductor layer 110a. The dielectric layer 130 is removed by a laser ablation, or a photolithography process using a photoresist film.

Referring to FIG. 5, a conductive paste 120a for a front electrode is applied on the anti-reflection coating layer 112. The conductive paste 120a for a front electrode may include a conductive powder, metallic glass, an inorganic additive for fire-through, and an organic vehicle as aforementioned, and may be applied by a screen printing method where the front electrode is formed

As described above, the conductive paste may include a metallic glass, and the metallic glass may be prepared using any kind of method, e.g., melt spinning, infiltration casting, gas atomization, ion irradiation, or mechanical alloying. The conductive paste 120a for a front electrode is dried.

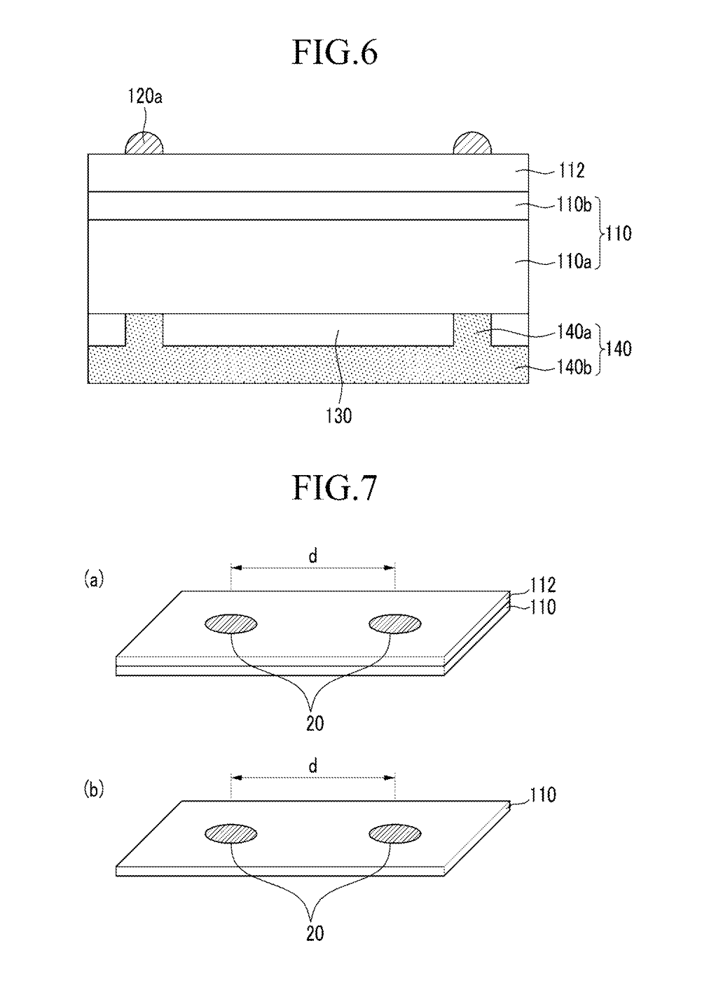

Referring to FIG. 6, a conductive paste (not shown) for a rear electrode 140 is applied on one side of the dielectric layer 130. The conductive paste (not shown) for a rear electrode 140 may include a conductive powder, for example, aluminum (Al), and may be applied and dried by a screen printing method where a rear electrode is formed.

However, the method is not limited to screen printing but may include inkjet printing and/or imprinting. The conductive paste for a rear electrode 140 is dried.

A semiconductor substrate 110 applied with the conductive paste for a front electrode 120a and the conductive paste (not shown) for a rear electrode is fired at higher temperatures in a furnace. The firing may be performed at a higher temperature than the melting temperature of the conductive paste, for example, at a temperature ranging from about 200 to 1000° C.

Referring to FIG. 1, the conductive paste 120a for a front electrode penetrates the anti-reflection coating 112 by the firing and contacts the lower semiconductor layer 110b, forming a front electrode 120.

On the other hand, a conductive paste (not shown) for a rear electrode contacts the lower semiconductor layer 110a through contact holes 135 formed in a dielectric layer 130. Referring to FIG. 6, the rear electrode 140 includes a plurality of contact portions 140a contacting the lower semiconductor layer 110a through the contact holes 135 in the dielectric layer 130, and a front portion 140b on the rear side of the semiconductor substrate 110.

However, the conductive paste 120a for a front electrode and the conductive paste (not shown) for a rear electrode may be respectively fired. The temperatures may be the same or different.

Herein, the conductive paste is applied to an electrode for a solar cell, but is not limited thereto and may be applied to all the electronic devices including an electrode.

The following examples illustrate this disclosure in more detail. However, it is understood that this disclosure is not limited by these examples.

### Example 1

Silver (Ag) powder, metallic glass Cu₄₃Zr₄₃Al₇Ag₇, and Sn powder are added to an organic vehicle including ethylcellulose binder and a butylcarbitol solvent. Herein, the silver (Ag) powder, the metallic glass Cu₄₃Zr₄₃Al₇Ag₇, the Sn powder, and the organic vehicle are respectively mixed in a ratio of 85 wt %, 4 wt %, 1 wt %, and 10 wt % based on a total weight of a conductive paste.

The mixture is kneaded with a 3-roll mill, preparing a conductive paste.

As shown in FIG. 7(a), silicon nitride (Si₃N₄) is formed on a silicon wafer (100 Ω/sq.) 110 to form an anti-reflection coating layer 112 by a chemical vapor-deposition (CVD) method, and then the conductive paste 20 is applied on the anti-reflection coating 112 by a screen-printing method. Herein, the conductive paste 20 is applied with a space of about 1.5 cm (d). The applied conductive paste 20 is heated to about 300° C. and then to about 850° C. using a belt furnace. The applied conductive paste 20 is cooled, forming an electrode sample.

### Example 2

An electrode sample is formed according to the same method as Example 1, except for preparing a conductive paste by respectively mixing silver (Ag) powder, metallic glass Cu₄₃Zr₄₃Al₇Ag₇, Sn powder, and an organic vehicle in a ratio of 81 wt %, 4 wt %, 5 wt %, and 10 wt % based on a total weight of the conductive paste.

### Example 3

An electrode sample is formed according to the same method as Example 1, except for preparing a conductive paste by respectively mixing silver (Ag) powder, metallic glass Cu₄₃Zr₄₃Al₇Ag₇, Sn powder, and an organic vehicle in a ratio of 76 wt %, 4 wt %, 10 wt %, and 10 wt % based on a total weight of the conductive paste.

### Example 4

An electrode sample is formed according to the same method as Example 1, except for preparing a conductive paste by respectively mixing silver (Ag) powder, metallic glass Cu₄₃Zr₄₃Al₇Ag₇, Sn powder, and an organic vehicle in a ratio of 66 wt %, 4 wt %, 20 wt %, and 10 wt % based on a total weight of the conductive paste.

### Example 5

An electrode sample is formed according to the same method as Example 1, except for preparing a conductive paste by respectively mixing silver (Ag) powder, metallic glass Cu₄₃Zr₄₃Al₇Ag₇, Sn powder, and an organic vehicle in a ratio of 56 wt %, 4 wt %, 30 wt %, and 10 wt % based on a total weight of the conductive paste.

### Example 6

An electrode sample is formed according to the same method as Example 1, except for preparing a conductive paste by respectively mixing silver (Ag) powder, metallic glass Cu₄₃Zr₄₃Al₇Ag₇, Sn powder, and an organic vehicle in a ratio of 51 wt %, 4 wt %, 35 wt %, and 10 wt % based on a total weight of the conductive paste.

### Comparative Example 1

An electrode sample is formed according to the same method as a conductive paste except using no Sn powder, but mixing silver (Ag) powder, metallic glass Cu₄₃Zr₄₃Al₇Ag₇, and an organic vehicle in a ratio of 86 wt %, 4 wt %, and 10 wt %, respectively, based on the total weight of the conductive paste.

### Comparative Example 2

A conductive paste is prepared by mixing silver (Ag) powder, metallic glass Cu₄₃Zr₄₃Al₇Ag₇, and an organic vehicle in a ratio of 86 wt %, 4 wt %, and 10 wt %, respectively.

As shown in FIG. 7(b), an electrode sample is formed by applying the conductive paste 20 on a silicon wafer (a bare silicon wafer) 110 with no anti-reflection coating layer by a screen printing method, and then heating and cooling the coated conductive paste 20, according to the same method as Example 1.

### EVALUATION

The electrode samples according to Examples 1 to 6 and Comparative Examples 1 and 2 are formed in multiple and evaluated resistance values thereof.

Table 1 shows resistances of the electrode samples according to Examples 1 to 6 and Comparative Examples 1 and 2.

TABLE 1

| | Resistance (Ω) |
|---|---|
| Example 1 | 50-100 |
| Example 2 | 20-40 |
| Example 3 | 30-40 |
| Example 4 | 40-50 |
| Example 5 | 43-55 |
| Example 6 | 160-240 |
| Comparative Example 1 | ∞ |
| Comparative Example 2 | 97.3 |

Resistance value in Table 1 is the sum of the resistance of the silicon wafer and contact resistance between a silicon wafer and an electrode sample. Herein, the resistance in Table 1 is proportional to contact resistance between a silicon wafer and an electrode sample, because the silicon wafer has constant resistance.

Referring to Table 1, the electrode samples according to Examples 1 to 6 have lower resistance than the electrode sample according to Comparative Example 1. Accordingly, the conductive paste including no inorganic additive for fire-through according to Comparative Example 1 is not fired through an anti-reflection coating layer and thus is not connected with a silicon substrate, while the conductive pastes including an inorganic additive for fire-through according to Examples 1 to 6 are fired through an anti-reflection coating layer and electrically connected to a silicon wafer.

On the other hand, the electrode samples according to Examples 1 to 5 have a lower resistance than the electrode sample according to Comparative Example 2, which is directly formed on a silicon wafer (bare silicon wafer). Accordingly, the electrode formed from a conductive paste including the inorganic additive for fire-through may have improved conductivity, compared with the electrode formed from a conductive paste directly applied on a silicon wafer.

While this disclosure has been described in connection with what is presently considered to be practical example embodiments, it is to be understood that the inventive concepts are not limited to the disclosed embodiments, but, on the contrary, are intended to cover various modifications and equivalent arrangements included within the spirit and scope of the appended claims.

What is claimed is:

1. A conductive paste, comprising:
a conductive powder;
a metallic glass;
an inorganic additive for fire-through; and
an organic vehicle.

2. The conductive paste of claim 1, wherein the inorganic additive for fire-through is fired through a film including one of a nitride, oxide, and a combination thereof at a temperature ranging from about 200 to 1,000° C.

3. The conductive paste of claim 2, wherein the film includes one of silicon nitride, silicon oxide, titanium nitride, titanium oxide, aluminum nitride, aluminum oxide, and a combination thereof.

4. The conductive paste of claim 2, wherein the inorganic additive for fire-through includes at least one of a metal having a larger oxidation capability than the one of the nitride, oxide, and combination thereof, and an oxide thereof.

5. The conductive paste of claim 1, wherein the inorganic additive for fire-through includes at least one selected from tin (Sn), zinc (Zn), strontium (Sr), magnesium (Mg), silver (Ag), lead (Pb), bismuth (Bi), molybdenum (Mo), technetium (Tc), ruthenium (Ru), rhodium (Rh), tungsten (W), rhenium (Re), osmium (Os), iridium (Ir), platinum (Pt), vanadium (V), manganese (Mn), chromium (Cr), iron (Fe), copper (Cu), cobalt (Co), palladium (Pd), nickel (Ni), and oxides thereof.

6. The conductive paste of claim 5, wherein the inorganic additive for fire-through includes at least one selected from tin (Sn), zinc (Zn), strontium (Sr), magnesium (Mg), tin oxide (SnO₂), silver oxide (Ag₂O), lead oxide (PbO), zinc oxide (ZnO), vanadium oxide (V₂O₃), manganese oxide (MnO), chromium oxide (Cr₂O₃), iron oxide (Fe₂O₃), copper oxide (CuO), cobalt oxide (CoO), palladium oxide (PdO), and nickel oxide (NiO).

7. The conductive paste of claim 1, wherein the inorganic additive for fire-through lowers a contact resistance of the conductive paste.

8. The conductive paste of claim 1, wherein the inorganic additive for fire-through is included in an amount of about 0.1 to about 35 wt % based on a total weight of the conductive paste.

9. The conductive paste of claim 8, wherein the conductive powder, the metallic glass, and the organic vehicle are included in a ratio of about 30 to 99 wt %, about 0.1 to 20 wt %, and a balance, respectively, based on the total weight of the conductive paste.

10. The conductive paste of claim 1, wherein the conductive powder includes one of silver (Ag), aluminum (Al), copper (Cu), nickel (Ni), and a combination thereof.

11. An electronic device comprising an electrode formed using the conductive paste according to claim 1.

12. The electronic device of claim 11, wherein the electrode has a contact resistance of less than or equal to about 100 mΩcm².

13. The electronic device of claim 11, wherein the electrode has resistivity of less than or equal to about 100 μΩcm.

14. A solar cell, comprising:
a semiconductor substrate; and
an electrode formed by using a conductive paste according to claim 1, the electrode electrically connected to the semiconductor substrate.

15. The solar cell of claim 14, further comprising:
an anti-reflection coating layer on one side of the semiconductor substrate, wherein the electrode is fired through the anti-reflection coating layer and contacts the semiconductor substrate.

16. The solar cell of claim 14, wherein the electrode has a contact resistance of less than or equal to about 100 mΩcm².

17. The solar cell of claim 14, wherein the electrode has resistivity of less than or equal to about 100 μΩcm.
